(19) United States
(12) Patent Application Publication
(10) Pub. No.: US 2007/0266349 A1
(43) Pub. Date: Nov. 15, 2007

(54) DIRECTED RANDOM VERIFICATION

(76) Inventors: Jesse Ethan Craig, South Burlington, VT (US); Scott T. Vento, Essex Junction, VT (US); Stanley B. Stanski, Essex Junction, VT (US); Andrew S. Wienick, Essex Junction, VT (US)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/382,371

(22) Filed: May 9, 2006

(51) Int. Cl. G06F 17/50; G06F 11/00; G01R 31/28

(52) U.S. Cl. 716/4; 714/30; 714/33; 714/733

(57) ABSTRACT

A directed random verification system and method analyzes a pair of generated test cases, from a pool of generated test cases which are capable of testing at least a portion of an untested coverage event, and finds a logical, deterministic crossover point between at least two test cases. Once a pair of test cases with at least one crossover point has been identified the method crosses a portion of the random number trace up to the crossover point with a portion of the second random number trace, which continues from the crossover point. The result is a new random number trace that is a combination of a portion of one test and a portion of another test. The new random number trace is sent to the stimulus generator as the new random number input.

### BACKGROUND OF THE INVENTION

1. Field of the Invention

The present invention relates to the field of verification of integrated circuit logic designs and more specifically to guiding stimulus generators to achieve specific coverage goals to direct random verification methods using genetic algorithms.

2. Background of the Invention

Verification of complex logic circuits cannot be accomplished in a reasonable amount of time, using a reasonable amount of resources, by testing every possible logic combination scenario at each logic circuit. During random logic verification it is difficult to reach all the coverage goals set forth by the verification engineer. Each test runs a random variation of the master verification test(s). It is unknown which of the desired coverage events a test will achieve until it is run. Because of this, it is difficult to ensure all the coverage goals are reached. Currently, verification methods run tests exhaustively until the coverage goals are coincidentally achieved. This exhaustive execution approach is time consuming and there is no guaranteed success.

### BRIEF SUMMARY OF THE INVENTION

The invention is a method of applying genetic algorithms in a directed random verification environment for a design under test (DUT). The method includes a random number generator that provides a random number input trace to a stimulus generator. The stimulus generator converts the random numbers into logic inputs for the DUT. A checker analyzes the output of the DUT to determine a test pass/fail status. The checker also identifies specific user defined test cases as they are tested and notifies the coverage monitor that a specific test was completed. A coverage event may be to test the logic for sending a data packet, and thus include several tests to completely cover the event. The checker sends the name of the coverage event, the actions taken during the test, and the input trace of random numbers used to produce the test case, to the coverage monitor. The events are stored in a table, or equivalent storage mechanism, in the coverage monitor associated with the actions executed during the test and the random input trace that generated the test.

The coverage monitor compares the coverage goals outlined in the test specifications with the list of coverage events. At a predetermined time, the coverage monitor takes an inventory of all specified coverage events that have not been covered and finds the test cases that have already been generated, which also include aspects or similarities to test cases, which would be required to achieve the missing coverage events. The method analyzes a pair of completed test cases from those identified as being similar to the required test case(s), and attempts to find a logical, deterministic crossover point between the two. A deterministic crossover point is an element, point, node, value, state, or the like, which is common to a pair of test cases. These deterministic crossover points are discovered by analyzing the actions executed by the two test cases and identifying a common point.

In some cases, more than one crossover point will be common to a set of test cases. In this scenario, the chosen crossover point may be randomly selected from the set of applicable crossover points, the first crossover point that was found may be used, the last crossover point may be employed, or some other logical selection method may be used to chose the crossover point at which the two test cases are crossed.

Once a pair of existing test cases with at least one deterministic crossover point has been identified the method crosses over the first portion of one of the random number input traces prior to the selected crossover point with the second portion of the other random number input trace, which continues after the selected crossover point. The result is a new random number input trace that is the same as the first portion of one test case and the second portion of another test case. The crossover point is the point at which the input trace changes from being the same as the first input trace to being the same as the second input trace. The new random number trace can be sent directly from the coverage monitor to the stimulus generator or from the random number generator as the new random number input. Likewise, any number of test cases may be crossed-over at multiple crossover points with any other number of test cases, including new test cases generated from the method described herein. Running a test case that has been developed as a result of crossing over known test cases guarantees the desired coverage event will be tested. Thus a desired test goal is achieved without having to write specific code to perform the test.

### BRIEF DESCRIPTION OF THE DRAWINGS

FIG. 1 is a block diagram of a verification system

FIG. 2 is a method of testing a DUT using directed random verification

FIG. 3 is an example of two test cases having a crossover point

FIG. 4 is a block diagram of an example computer system capable of executing computer readable programs.

### DETAILED DESCRIPTION

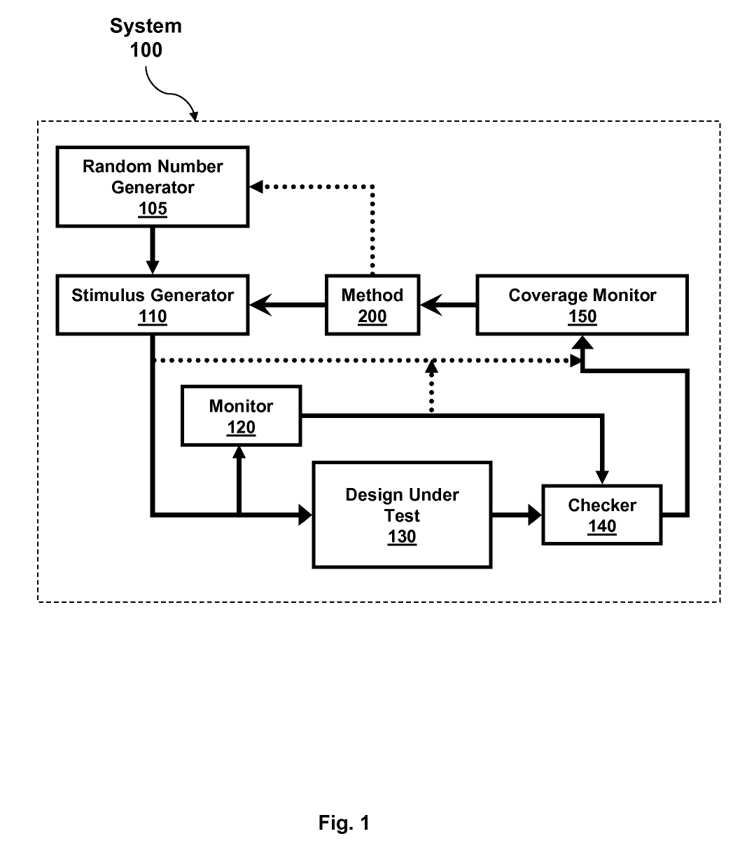

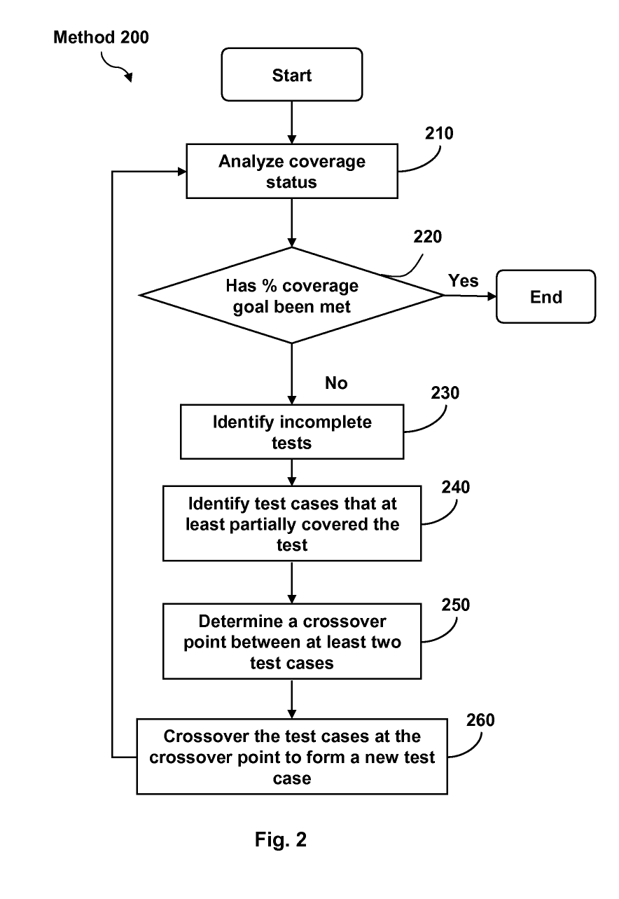

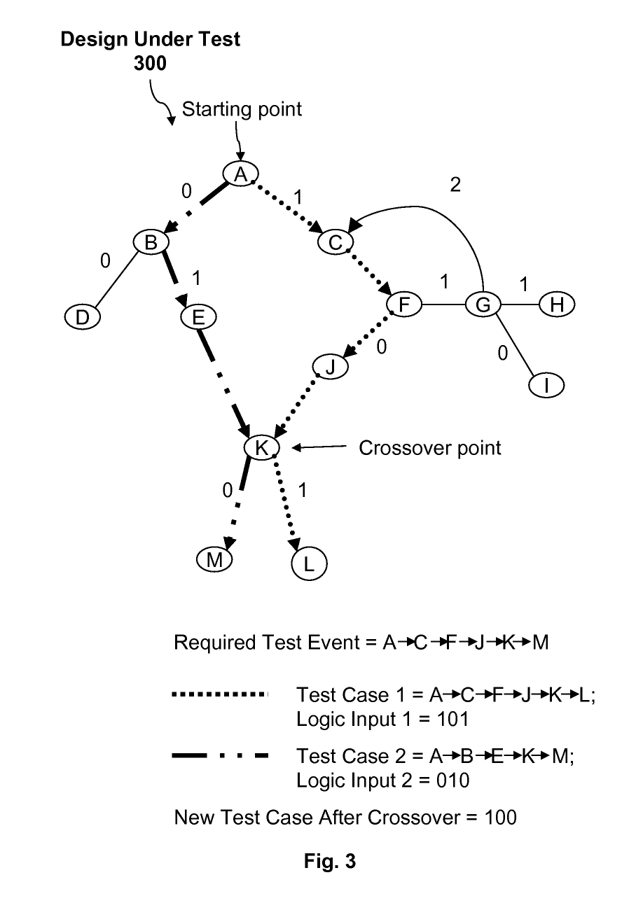

FIG. 1 shows a directed random verification system 100. System 100 includes a stimulus generator 110, a random number generator 105 which provides random number input to stimulus generator 110, a monitor 120, a design under test (DUT) 130, a checker 140, a coverage monitor 150, and a method 200, which will be explained in detail in FIG. 2. The random numbers generated by random number generator 105 define an input trace for a test case, for example: 72, 64, 32, 54, 91, generates a test case, which will test a certain logic feature of the design. Stimulus generator 110 converts the random numbers into application specific sequences of logic inputs (e.g. a bit string of 0's and 1's that perform an event such as sending a data packet) and sends the logic inputs to DUT 130 and monitor 120. Alternatively, stimulus generator 110 sends the logic inputs directly to coverage monitor 150. Checker 140 analyzes the output of DUT 130 and the original logic inputs from monitor 120 to determine a pass/fail status and sends the information to coverage monitor 150. Checker 140 also identifies specific user defined test cases as they occur and notifies coverage monitor 150 that a specific test event was covered. Checker 140 sends the name of the covered event, the actions taken by the test case, and their order, to coverage monitor 150. For example, the event represented by the sequence of actions A→B→E→K→L shown in FIG. 3. The events are stored in a table or other form of memory in coverage monitor 150 along with the random number input trace that generated the test case. Coverage monitor 150 compares the coverage goals outlined in the test specifications with the list of covered events. At a predetermined time, coverage monitor 150 takes an inventory of all specified coverage goals that have not been covered and sends the data to method 200. Method 200 may reside in coverage monitor 150 or be run as a separate program. Method 200 then finds test cases, which have already been generated, and have the capability of testing at least a portion of a missing event to create a new test case which will cover all or part of the missing event. The new test case may also be a result of several test cases having multiple crossover points, which are crossed over at their respective crossover points. Method 200 sends the new test case (either from coverage monitor 150 or random number generator 105) to stimulus generator 110 for processing. Method 200 is described in detail in FIG. 2 below.

FIG. 2 shows a flow diagram of a test verification method 200. In step 210 the method analyzes the coverage status to determine how many required tests have been covered. In step 220, method 200 compares the number of covered tests to a previously determined coverage goal, for example a percentage of total events desired to be tested. If the coverage goal has been met, method 200 ends; if not, method 200 continues to step 230. In step 230, method 200 identifies required tests that have not been completed. In step 240, method 200 identifies completed tests and their respective test cases, which cover at least a portion of the missing coverage event. In step 250, the method identifies a common point (e.g. element, node, state, value, etc.) between at least two test cases identified in step 240. This is called the crossover point. In step 260, method 200 creates a new test case by crossing over the first portion of the input trace, up to the crossover point, of the first test case with the second portion directly following the crossover point of the input trace of the second test case to create a third test case. The third test case will cover the desired missing coverage event. For example, test case 1 has an input trace of 92, 71, 63, 45, 84 and test case two has an input trace of 34, 46, 16, 72, 83. The crossover point lies between “63” and “45” of the first input trace (test case 1) and between “16” and “72” of the input trace for test case 2. The third test case is thus defined by the first portion of the first input trace, “92, 71, 63” and “72, 83” of the second input trace to create a third input trace: 92, 71, 63, 72, 83. Likewise, any number of test cases may be used to create the third test case as long as they each have at least one point in common with at least one other test case.

Method 200 sends the newly created test case to stimulus generator 110 directly from coverage monitor 150 or sends the new test case to random number generator 105 for processing. An example of crossover point identification of step 240 and crossover step 260 is shown in FIG. 3.

FIG. 3 shows an example DUT 300 and a missing test coverage event denoted by A→C→F→J→K→M. Also shown in FIG. 3 are two test cases. Test case 1 covers the event A→C→F→J→K→L and is achieved through the logic input: 101. Likewise, Test case 2 covers the event A→B→E→K→M and is achieved through the logic input: 010. The common point between the two tests is node ‘K’. By crossing the input traces of test cases 1 and 2 at the crossover point, K, the resulting logic input is 100 and the desired event A→C→F→J→K→M can be covered.

Below is an example of pseudo code which may be used to implement the directed random verification program on a computer system.

begin

while( predetermined amount of traditional verification has not been
executed )
begin

run using traditional methods;

end;
while( some coverage goals not achieved )
begin

foreach( coverage goal not achieved )
begin

cg := unachieved coverage goal;
foreach( test case previously executed )
begin

tc := previously executed testcase;
evaluate_relevance( tc, eg ); // evaluate how useful
‘tc’

// might be to achieving the goal ‘cg’

end;
foreach( relevant previously executed testcase )

// relevant is when relevancy > some threshold

begin

tc1 = relevant previously executed testcase;
foreach( relevant previously executed testcase )
begin

tc2 = relevant previously executed testcase;
if( tc1 != tc2 ) // don't cross a test case with
itself
begin

cps[ ] := find_crossover_point( tc1, tc2 );
if get_number_of_elements( cps ) > 1
begin
cpt :=

choose_random_crossover( cps[ ] );

else cpt = cps[0];

tc3 :=
cross( tc1, tc2, cpt ); // cross at cpt

add_to_new_testcases( tc3 );
end;

end;

end;

end;

end;
execute_new_testcases( );

end;

end;

It should also be noted that more than two test cases can be used for crossover purposes where portions of a first test case cross with a portion of a second test case, which in turn crosses with a third test case, which in turn could cross with yet another portion of the first test case and so on. Furthermore, a newly developed test case may also be crossed over with any other test case so long as there is a point in common between them. Thus the invention is not limited to two test cases or a single crossover point.

It would be recognized by one of ordinary skill in the art that variations in crossover step 260 may be performed using other patterned techniques without deviating from the spirit and scope of the invention. The crossover technique described herein and shown if the accompanying figures is only for illustrative purposes and in no way limits the possible variations of crossover techniques used to practice the invention. Furthermore, the invention is not limited to the application of logic verification, but can be applied to any industry requiring a method of verification that is more robust and takes fewer resources than current industry methods. For example, this invention could be practiced in software debugging environments for the IT industry, security industry, simulators for the aerospace and defense industries, research and development, and any industry that requires significant testing of products or environments such as automated test pattern generation programs for manufacturing test.

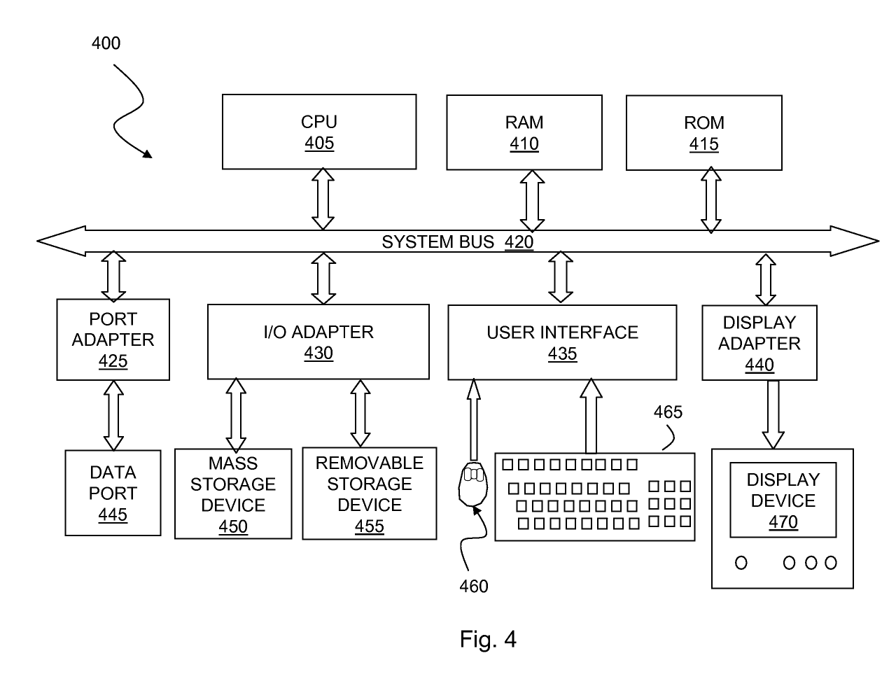

FIG. 4 illustrates a block diagram of a generic computer system which can be used to implement the method described herein. The method may be coded as a set of instructions on removable or hard media for use by the general-purpose computer. FIG. 4 is a schematic block diagram of a general-purpose computer for practicing the present invention. FIG. 4 shows a computer system 400, which has at least one microprocessor or central processing unit (CPU) 405. CPU 405 is interconnected via a system bus 420 to a random access memory (RAM) 410, a read-only memory (ROM) 415, an input/output (I/O) adapter 430 for connecting a removable and/or program storage device 455 and a mass data and/or program storage device 450, a user interface 435 for connecting a keyboard 465 and a mouse 460, a port adapter 425 for connecting a data port 445 and a display adapter 440 for connecting a display device 470. ROM 415 contains the basic operating system for computer system 400. Examples of removable data and/or program storage device 455 include magnetic media such as floppy drives, tape drives, portable flash drives, zip drives, and optical media such as CD ROM or DVD drives. Examples of mass data and/or program storage device 450 include hard disk drives and non-volatile memory such as flash memory. In addition to keyboard 465 and mouse 460, other user input devices such as trackballs, writing tablets, pressure pads, microphones, light pens and position-sensing screen displays may be connected to user interface 435. Examples of display device 470 include cathode-ray tubes (CRT) and liquid crystal displays (LCD).

A computer program may be created by one of skill in the art and stored in computer system 400 or a data and/or removable program storage device 465 to simplify the practicing of this invention. In operation, information for the computer program created to run the present invention is loaded on the appropriate removable data and/or program storage device 455, fed through data port 445 or entered using keyboard 465. A user controls the program by manipulating functions performed by the computer program and providing other data inputs via any of the above mentioned data input means. Display device 470 provides a means for the user to accurately control the computer program, if required, and perform the desired tasks described herein.

What is claimed is:

1. A method of directing random verification comprising the steps of:
identifying an untested event;
identifying at least a first test case and a second test case, each testing at least a portion of the untested event;
identifying a crossover point; and
deriving a third test case by crossing the first test case and the second test case at the crossover point.

2. The method of claim 1, wherein a plurality of test cases are crossed over to derive at least one test case having portions of the plurality of test cases and the respective plurality of crossover points; and tests the untested event.

3. The method of claim 1, further comprising the steps of:
providing a first input trace and second input trace as input to a stimulus generator, wherein the first input trace and the second input trace are created using a random number generator; and
generating the first test case and the second test case using the first and second input traces respectively;

4. The method of claim 3, wherein the third test case is derived by crossing a portion of the first input trace with a portion of the second input trace to generate a third input trace, which is executed by the stimulus generator.

5. The method of claim 1, wherein the step of identifying a crossover point comprises comparing each point of the first test case to each point of the second test case to find at least one point in common.

6. The method of claim 1, wherein the method terminates when a predetermined number of events have been tested.

7. A directed random verification system comprising:
a random number generator which generates and sends an input trace to a stimulus generator;
the stimulus generator generates a test case and corresponding logic input from the received input trace and sends the logic input to a design under test (DUT), and the stimulus generator sends the test case to a coverage monitor;
the DUT processes the logic input and produces a test result;
the coverage monitor stores the test case and determines whether a predetermined goal has been satisfied;
the verification system derives and executes a new test case from at least two completed test cases, wherein the at least two completed test cases cover at least a portion of a predetermined coverage event and have at least one crossover point.

8. The verification system of claim 7, wherein the system further comprises a monitor which receives the test case from the stimulus generator sends the test case to the coverage monitor.

9. The verification system of claim 8, wherein the system further comprises a checker, which receives the test case from the monitor and sends the test case to the coverage monitor.

10. The verification system of claim 9, wherein the checker compares the test result from the DUT with an expected test result to determine a pass/fail status of a test event and sends the test result to the coverage monitor.

11. The verification system of claim 7, wherein the predetermined goal is a plurality of tested events.

12. The verification system of claim 7, wherein the new test case comprises a portion of a plurality of test cases, each having at least one crossover point with at least one other test case in the plurality of test cases.

13. The verification system of claim 7, wherein the coverage monitor further comprises a list of events tested, the respective random number input trace for each of the test cases corresponding to each of the events tested, and a list of required events to cover during test.

14. A computer readable program device for performing directed random verification comprising:
a computer system having a memory wherein a design under test (DUT) is read into the memory;
a random number generator program, wherein the random number generator program generates a random number input trace for a stimulus generator program, which further generates a test case for the DUT;
a coverage monitoring program which calculates a new test coverage value and compares a predetermined test coverage goal with the new coverage value;
if the new coverage value is less than the test coverage goal, the coverage monitoring program identifies an untested event;
a directed random verification program identifies at least two completed test cases which at least partially cover the untested event and have at least one crossover point; the
directed random verification program then selects a crossover point and crosses the completed test cases at the selected crossover point to develop a third test case which satisfies at least a portion of the untested event.

15. The computer readable program device of claim 14, wherein the random number generator program provides a first random number input trace and a second random number input trace both of which are used by the stimulus generator program to generate the first test case and the second test case, respectively.

16. The computer readable program device of claim 15, wherein the coverage monitoring program stores the first and second test cases and the first and second random number input traces in a memory structure.

17. The computer readable program device of claim 15, wherein the directed random verification program crosses the first random number input trace with the second random number input trace to generate a third input trace from which the stimulus generator generates the third test case.

18. The computer readable program device of claim 14, wherein the directed random verification program identifies at least one crossover point by comparing each point of the first test case to each point of the second test case.

19. The computer readable program device of claim 14, further comprising a monitor program which tracks the logic input to the DUT from the stimulus generator program.

20. The computer readable program device of claim 14, wherein the program terminates when the test coverage goal has been satisfied.
